(19) United States
(12) Patent Application Publication
(10) Pub. No.: US 2024/0010892 A1
(43) Pub. Date: Jan. 11, 2024

(54) APPLICATION OF LASER-RELEASABLE COMPOSITION

(71) Applicant: Microcosm Technology CO., LTD, Tainan City (TW)

(72) Inventors: Bo-Hung LAI, Tainan City (TW); Tang-Chieh HUANG, Tainan City (TW)

(73) Assignee: Microcosm Technology CO., LTD, Tainan City (TW)

(21) Appl. No.: 18/334,675

(22) Filed: Jun. 14, 2023

(30) Foreign Application Priority Data
Jul. 7, 2022 (TW) 111125507

(51) Int. Cl. C09J 179/08

(52) U.S. Cl. CPC C09J 179/08; C09J 2301/502; C09J 2203/326

(57) ABSTRACT

The present invention provides a temporary bonding method comprising: providing a stack comprising: a first substrate, an adhesive layer, a second substrate, and a sacrificial layer; and applying laser energy to the sacrificial layer to facilitate separation of the first substrate from the second substrate. The sacrificial layer in this invention is soluble in alkaline aqueous solution and therefore if there is a residual sacrificial layer, it can be easily removed with an alkaline aqueous solution to avoid damaging the component.

This application claims priority under 35 U.S.C. § 119 to Taiwanese Patent Application No. 111125507, filed Jul. 7, 2022, the entirety of which is incorporated by reference herein.

### BACKGROUND OF THE INVENTION

### Field of the Invention

The present invention relates to a laser-releasable composition for forming a sacrificial layer used in a temporary bonding process or in a redistribution layer formation process.

### Description of the Prior Art

Temporary wafer bonding (TWB) generally refers to a process of attaching a component wafer or a microelectronic substrate to a carrier wafer or substrate by polymeric bonding materials. In order to make the wafer more heat-dissipating during use, prolong its life and facilitate later system packaging, it is usually necessary to thin the component wafer to less than 50 μm. Generally speaking, the component wafer is temporarily bonded to a thicker carrier glass, and then etching, grinding or other process for thinning is performed to the back of the wafer. Also, through-silicon vias (TSV), redistribution layers, bonding pads and other circuit features can be formed. During backside processing (need to withstand repeated cycles between ambient temperature and extremely high temperature (greater than 250° C.), mechanical shocks generated from wafer processing and transfer steps, and strong mechanical forces (such as the force applied during the wafer backside grinding process used to thin the component wafer)), the carrier wafer supports the fragile component wafer. After all the processing is completed, the adhesive layer is deactivated by external light, electricity and heat to separate (i.e., peel off) the component wafer from the carrier, and further operation is performed for cleaning.

In the conventional technology, the temporary bonding layer mainly includes UV debonding glue, thermal debonding glue, solvent debonding glue and laser debonding glue. However, the UV debonding glue and the thermal debonding glue have a heat resistance temperature of about 120-150° C. and cannot withstand the temperature up to 260° C., and are easily affected by the ambient environment, causing the debonding reaction to occur early. The disadvantage of solvent debonding glue is that it has poor solvent resistance and has limitations in the manufacturing processes. Laser debonding has better heat resistance and chemical resistance, but it is easy to produce residual glue during the debonding process, which needs to be removed with a high-polarity solvent, causing other materials on the component to be corroded, so it also has limitations in use.

### SUMMARY OF THE INVENTION

In view of the technical problems described above, an object of the present invention is to provide a novel temporary bonding method, which can use an alkaline aqueous solution to remove the residual glue that may be produced during the debonding process, thereby greatly reducing the possibility of components being corroded.

Another object of the present invention is to provide a novel method of forming a microelectronic structure, which can use an alkaline aqueous solution to remove the residual glue that may be produced during the debonding process, thereby greatly reducing the possibility of components being corroded.

To achieve the above objects, the present invention provides a temporary bonding method, which comprises: providing a stack comprising: a first substrate having an upper surface and a lower surface; an adhesive layer in contact with the lower surface; a second substrate having a first surface; and a sacrificial layer disposed between the first surface and the adhesive layer; and applying laser energy to the sacrificial layer to facilitate separation of the first substrate from the second substrate, wherein the sacrificial layer is formed by a composition comprising an alkali-soluble polymer; and a solvent for dispersing or dissolving the alkali-soluble polymer, wherein the alkali-soluble polymer contains a divalent residue of a diamine having a carboxyl group, and the alkali-soluble polymer comprises polyamic acid, polyimide or polyamideimide.

Preferably, the method further comprises washing the adhesive layer with an alkaline aqueous solution to remove the sacrificial layer remaining on a surface of the adhesive layer after the step of applying laser energy to the sacrificial layer.

Preferably, the alkaline aqueous solution is 3% to 5% by weight of an aqueous alkali metal hydroxide solution or an aqueous alkali metal carbonate solution.

Preferably, the divalent residue of the diamine having the carboxyl group comprises the following group:

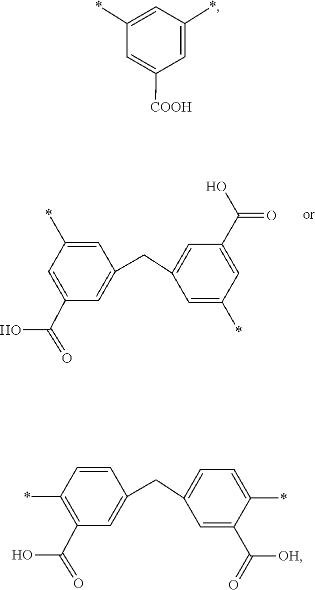

wherein * indicates a connection point.

Preferably, the sacrificial layer has a thermal expansion coefficient of less than 50 ppm/° C.

The present invention further provides a method of forming a microelectronic structure, which comprises: forming a sacrificial layer on a surface of a substrate; and forming a redistribution layer on the sacrificial layer, wherein the sacrificial layer is formed by a composition comprising an alkali-soluble polymer; and a solvent for dispersing or dissolving the alkali-soluble polymer, wherein the alkali-soluble polymer contains a divalent residue of a diamine having a carboxyl group, and the alkali-soluble polymer comprises polyamic acid, polyimide or polyamideimide.

Preferably, the method further comprises forming one or more additional redistribution layers on the redistribution layer.

Preferably, the method further comprises applying laser energy to the sacrificial layer to separate the redistribution layer from the substrate after forming the redistribution layer.

Preferably, the method further comprises washing the redistribution layer with an alkaline aqueous solution to remove the sacrificial layer remaining on a surface of the redistribution layer after applying laser energy to the sacrificial layer.

Preferably, the alkaline aqueous solution is 3 to 5% by weight of an aqueous alkali metal hydroxide solution or an aqueous alkali metal carbonate solution.

Preferably, the divalent residue of the diamine having the carboxyl group comprises the following group:

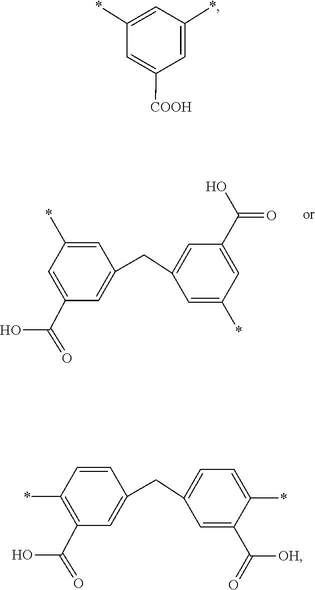

wherein * indicates a connection point.

According to the present invention, a temporary bonding method and a method of forming a microelectronic structure can be obtained that can easily remove the residual glue produced in the debonding process with an alkaline aqueous solution.

### BRIEF DESCRIPTION OF THE DRAWINGS

FIG. 1(a), FIG. 1(b), and FIG. 1(c) depict a flowchart for schematically illustrating the temporary bonding method of the present invention.

FIG. 2(a), FIG. 2(b), FIG. 2(c), FIG. 2(d), FIG. 2(e), FIG. 2(f), FIG. 2(g), and FIG. 2(h) depict a flowchart for schematically illustrating the method for forming a microelectronic structure of the present invention.

### DETAILED DESCRIPTION OF THE EMBODIMENTS

The present invention provides a temporary bonding method, which comprises: providing a stack comprising: a first substrate having an upper surface and a lower surface; an adhesive layer in contact with the lower surface; a second substrate having a first surface; and a sacrificial layer disposed between the first surface and the adhesive layer; and applying laser energy to the sacrificial layer to facilitate separation of the first substrate from the second substrate, wherein the sacrificial layer is formed by a composition comprising an alkali-soluble polymer; and a solvent for dispersing or dissolving the alkali-soluble polymer, wherein the alkali-soluble polymer contains a divalent residue of a diamine having a carboxyl group, and the alkali-soluble polymer comprises polyamic acid, polyimide or polyamideimide.

As described above, in the present invention, the composition for forming the sacrificial layer (or referred to as a laser releasable composition) comprises an alkali-soluble polymer; and a solvent for dispersing or dissolving the alkali-soluble polymer, wherein the alkali-soluble polymer contains a divalent residue of a diamine having a carboxyl group, and the alkali-soluble polymer comprises polyamic acid, polyimide or polyamideimide.

The polyamic acid is preferably synthesized by condensation polymerization by mixing dianhydride and diamine monomers in a specific solvent to form a polyamic acid precursor solution. Next, a capping agent is preferably added to eliminate terminal functional groups in order to prevent possible subsequent aging. The specific solvent includes, but is not limited to: cyclohexanone, cyclopentanone, propylene glycol monomethyl ether, N-methyl-2-pyrrolidone, N,N-dimethylacetamide, γ-butyrolactone, ethyl 3-ethoxy propionate, propylene glycol methyl ether acetate, ethyl lactate or a combination of two or more of the aforementioned solvents.

In a preferred embodiment, the polyimide is mainly formed by polymerizing dianhydride monomers and diamine monomers, and at least one diamine monomer has a carboxyl functional group.

In a preferred embodiment, the polyamideimide is mainly formed by polymerizing dianhydride monomers, diamine monomers and aromatic dicarbonyl monomers, at least one diamine monomer has a carboxyl functional group, and the mole number of the aromatic dicarbonyl monomer account for 10%-50% of the total mole number of the dianhydride monomer and the aromatic dicarbonyl monomer. In a preferred embodiment, the thermal expansion coefficient of the sacrificial layer is less than 50 ppm/° C.

In the present invention, the divalent residue of the diamine having the carboxyl group comprises the following group:

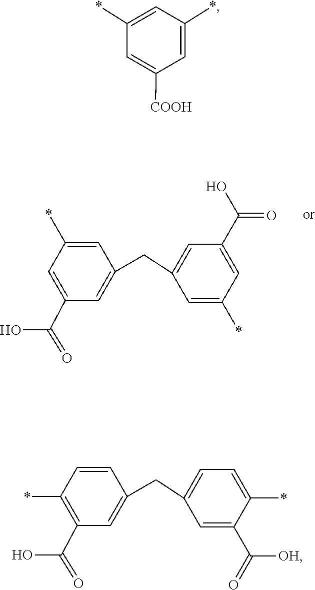

wherein * indicates a connection point.

Other diamine monomers applicable to the present invention include but are not limited to: 2-(trifluoromethyl)-1,4-phenylenediamine, bis(trifluoromethyl)benzidine (TFDB), 4,4′-Oxydianiline (ODA), para-Methylene Dianiline (pMDA), meta-Methylene Dianiline (mMDA), 1,3-bis(3-aminophenoxy)benzene (133APB), 1,3-bis(4-aminophenoxy)benzene (134APB), 2,2′-bis[4(4-aminophenoxy)phenyl]hexafluoropropane (4BDAF), 2,2′-bis(3-aminophenyl)hexafluoropropane (33-6F), 2,2′-bis(4-aminophenyl)hexafluoropropane (44-6F), bis(4-aminophenyl)sulfone (4DDS), 3-aminophenyl)sulfone (3DDS), 2,2-Bis[4-(4-aminophenoxy)-phenyl]propane (6HMDA), 2,2-Bis(3-amino-4-hydroxy-phenyl)-hexafluoropropane (DBOH), 4,4′-Bis(3-amino phenoxy)diphenyl sulfone (DBSDA), 9,9-Bis(4-aminophenyl)fluorine (FDA), 9,9-Bis(3-fluoro-4-aminophenyl)fluorine (FFDA) or a combination of two or more of the aforementioned diamine monomers.

The dianhydride monomers applicable to the present invention include but are not limited to: 4,4′-(4,4′-isopropyldiene diphenoxy) bis(phthalic anhydride), 4,4′-(hexafluoroisopropylidene)diphthalic anhydride, 3,3′,4,4′-diphenyl ketone tetracarboxylic dianhydride, 3,3′,4,4′-biphenyl tetracarboxylic dianhydride, 2,3,3′,4′-biphenyltetracarboxylic dianhydride, 4,4′-oxydiphthalic anhydride, 3,3′,4,4′-diphenylsulfone tetracarboxylic dianhydride, biscarboxyphenyldimethylsilane dianhydride, bisdicarboxyphenoxydiphenyl sulfide dianhydride, sulfonyl diphthalic anhydride, 1,2,3,4-cyclobutane tetracarboxylic dianhydride, cyclohexane-1,2,4,5-tetracarboxylic dianhydride, 1,1′-bi(cyclohexyl)-3,3′,4,4′-tetracarboxylic dianhydride, 1,1′-bi(cyclohexane)-2,3,3′,4′-tetracarboxylic dianhydride, 1,1′-bi(cyclohexane)-2,2′,3,3′-tetracarboxylic dianhydride, 4,4′-methylene bis(cyclohexane-1,2-dicarboxylic anhydride), 4,4′-(propane-2,2-diyl) bis(cyclohexane-1,2-dicarboxylic anhydride), 4,4′-oxybis(cyclohexane-1,2-dicarboxylic anhydride), 4,4′-thiobis(cyclohexane-1,2-dicarboxylic anhydride), 4,4′-sulfonylbis(cyclohexane-1,2-dicarboxylic anhydride), 4,4′-(dimethylsilanediyl)bis(cyclohexane-1,2-dicarboxylic anhydride), 4,4′-(tetrafluoropropane-2,2-diyl)bis(cyclohexane-1,2-dicarboxylic anhydride), octahydropentalene-1,3,4,6-tetracarboxylic dianhydride, bicyclo[2.2.1]heptane-2,3,5,6-tetracarboxylic dianhydride, (8aS)-hexahydro-3H-4,9-methylfuran[3,4-g]isoamylene-1,3,5,7(3aH)-tetraketone, bicyclo[2.2.2]octane-2,3,5,6-tetracarboxylic dianhydride, bicyclo[2.2.2] oct-5-ene-2,3,7,8-tetracarboxylic dianhydride, tricyclo[4.2.2.02,5]decane-3,4,7,8-tetracarboxylic dianhydride, tricyclo[4.2.2.02,5]dec-7-ene-3,4,9,10-tetracarboxylic dianhydride or a combination of two or more of the aforementioned dianhydride monomers.

The aromatic dicarbonyl monomers applicable to the present invention include but are not limited to: 4,4′-biphenyldicarbonyl chloride (BPC), isophthaloyl chloride (IPC), terephthaloyl chloride (TPC) or a combination of two or more of the aforementioned aromatic dicarbonyl monomers.

As described above, it is preferable to use a capping agent to improve the stability of the final product by capping the terminal amine and consuming excess diamine in the reaction solution. It is preferable to use aromatic monoanhydrides as the capping agent. A particularly preferred capping agent is phthalic anhydride. The molar supply ratio of the dianhydride monomer, the diamine monomer and the capping agent is preferably about 0.7:1:0.3 to about 0.98:1:0.02, more preferably about 0.85:1:0.15 to about 0.95:1:0.05.

The solvent for dispersing or dissolving the alkali-soluble polymer includes but is not limited to cyclohexanone, cyclopentanone, propylene glycol monomethyl ether, N-methyl-2-pyrrolidone, N,N-dimethyl acetamide, γ-butyrolactone, ethyl 3-ethoxypropionate, propylene glycol methyl ether acetate, ethyl lactate or a mixture of two or more of the aforementioned solvents.

In the present invention, the sacrificial layer formed by the composition can be removed by an alkaline aqueous solution. The alkaline aqueous solution is preferably 3 to 5% by weight of an aqueous alkali metal hydroxide solution or an aqueous alkali metal carbonate solution. In some embodiments, the heat-resistant temperature of the sacrificial layer is 350-450° C.

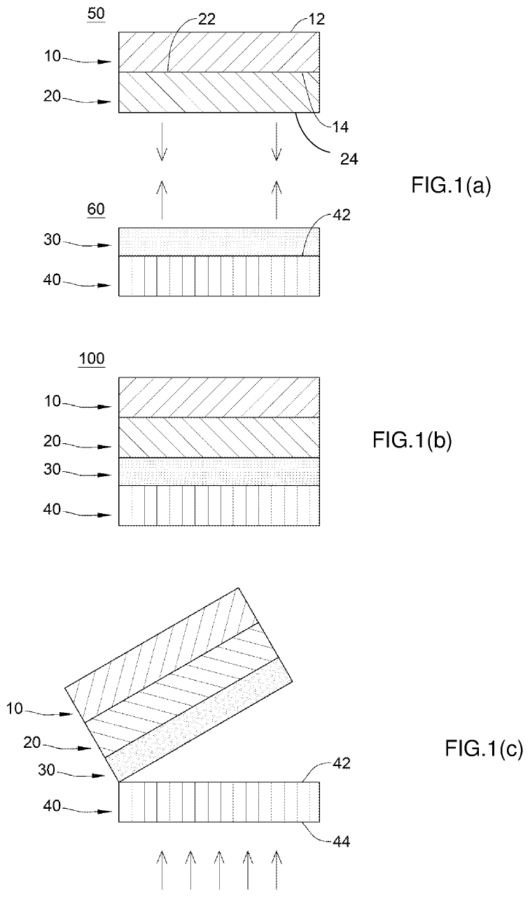

With reference to FIG. 1(a), which schematically illustrates the step of providing a stack of the present invention. Also refer to FIG. 1(b), which schematically illustrates the structure of the stack of the present invention. The stack 100 may be provided by the following steps: providing a stack precursor 50 comprising a first substrate 10 and an adhesive layer 20; and bonding the stack precursor 50 to a second substrate 40 through a sacrificial layer 30. As shown in FIG. 1 (a), the first substrate 10 has an upper surface 12 and a lower surface 14 opposite to the upper surface 12, and the adhesive layer 20 directly contacts the lower surface 14 of the first substrate 10 with its upper surface 22 (that is, there is no intermediate layer between the two layers). The upper surface (first surface) 42 of the second substrate 40 is bonded to the lower surface 24 of the adhesive layer 20 through the sacrificial layer 30.

In the present invention, the first substrate can be a component wafer, including but not limited to micro-electromechanical systems (MEMS), micro-sensors, integrated circuits and power semiconductors. The lower surface 14 of the first substrate may have structures such as solder bumps, metal posts, and metal pillars.

The composition used to form the adhesive layer 20 is not particularly limited, and can be selected from commercially available adhesive compositions, as long as it can form a layer with the above-mentioned adhesive properties, and at the same time, the solvent can be removed by heating. These compositions are typically organic and comprise polymers or oligomers dissolved or dispersed in the solvent system. The polymer or oligomer can generally be selected from: cycloolefins, epoxy resins, acrylics, silicones, styrenes, vinyl halides, vinyl esters, polyamides, polyimides, polysulfones, polyethersulfones, cycloolefins, polyolefin rubbers, polyurethanes, ethylene-propylene rubbers, polyamide esters, polyimide esters, polyacetals, polyvinyl butyral or a mixture thereof. Typical solvent systems depend on the choice of polymers or oligomers.

The adhesive layer 20 can be applied to the lower surface 14 of the first substrate 10 by any known coating process, including but not limited to: dip coating, roll coating, slot coating, die coating, screen printing or spraying etc. In addition, before the coating is applied to the surface of the first substrate or the second substrate, it can be formed as a free-standing film, and the adhesive layer 20 can be applied to the lower surface 14 of the first substrate 10 by means of transfer attaching.

After the adhesive layer 20 is coated on the lower surface 14 of the first substrate 10, the solvent is removed by heating at about 50° C. to 150° C. for about 60 seconds to about 10 minutes. Afterwards, the adhesive layer 20 is bonded to the sacrificial layer 30 on the second substrate 40 by applying pressure, and then the adhesive layer 20 is cured after baking, so that the stack 100 shown in FIG. 1(b) can be obtained. The resulting adhesive layer 20 has a thickness of about 1 μm to about 50 μm.

In this embodiment, the second substrate 40 is a carrier wafer as a carrier substrate. The substrate 40 has a first surface 42 (upper surface) and a second surface 44 (lower surface) opposite to the first surface 42. The second substrate 40 preferably comprises a transparent wafer or any other transparent (to the laser energy) substrate that allows the laser energy to pass through the carrier substrate. Examples of the second substrate 40 include, but are not limited to: glass, Corning Gorilla glass, sapphire.

As shown in FIG. 1(a), another stack precursor (second precursor) 60 includes a second substrate 40 and a sacrificial layer 30 on the second substrate 40. The composition for forming the sacrificial layer can be applied to the second substrate 40 by any known coating method to form the sacrificial layer 30 on the first surface 42 of the second substrate 40. After the composition is applied to the first surface 42, the composition is heated to a temperature of about 60° C. to about 150° C. for about 30 seconds to about 20 minutes to remove the solvent. Then, curing is carried out at 200-350° C. for about 20 minutes to about 90 minutes. After the adhesive layer 20 is bonded to the sacrificial layer 30 on the second substrate 40 by heat press and then undergoes a curing step, the first substrate 10 can be bonded to the second substrate 40 to form the stack 100 as shown in FIG. 1(b).

Optionally, the stack 100 can be processed. After other processing procedures, all or part of the sacrificial layer 30 can be debonded by laser decomposition or ablation, so as to separate the first substrate 10 and the second substrate 40. Suitable laser wavelengths are from about 200 nm to about 400 nm, preferably from about 300 nm to about 360 nm. After the separation, the sacrificial layer substance remaining on the adhesive layer 20 can be removed with an alkaline aqueous solution. In this embodiment, as shown in the direction of the arrow in FIG. 1(c), the laser is applied through the second substrate 40 so that the sacrificial layer 30 is exposed to the laser, which makes the sacrificial layer lose its adhesion property to separate the first substrate 10 from the second substrate 40.

The compositions for forming the sacrificial layer described herein can also be used as the laser release sacrificial layer during the formation of the redistribution layer (“RDL”), especially in the RDL-first/chip-last packaging of wafer or panel-level processes, in which it is very useful for minimizing or even avoiding known-good die loss during packaging.

Therefore, the present invention further provides a method of forming a microelectronic structure. The method comprises: forming a sacrificial layer on a surface of a substrate; and forming a redistribution layer on the sacrificial layer, wherein the sacrificial layer is formed of a composition comprising an alkali-soluble polymer; and a solvent for dispersing or dissolving the alkali-soluble polymer, wherein the alkali-soluble polymer contains a divalent residue of a diamine having a carboxyl group, and the alkali-soluble polymer comprises polyamic acid, polyimide or polyamideimide.

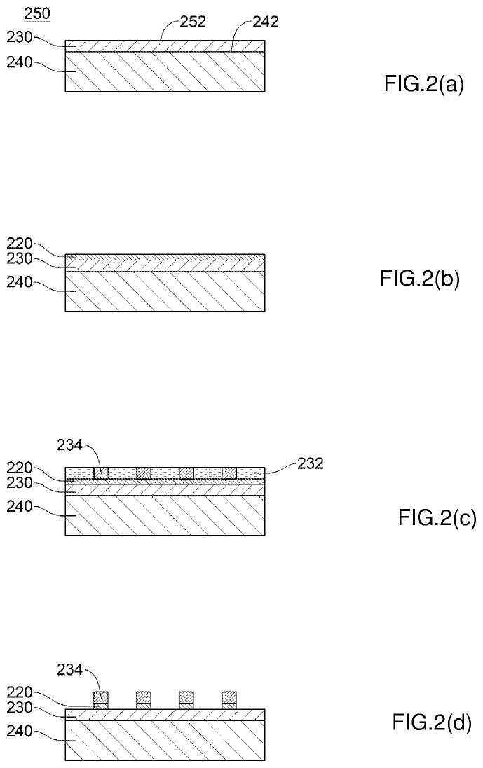

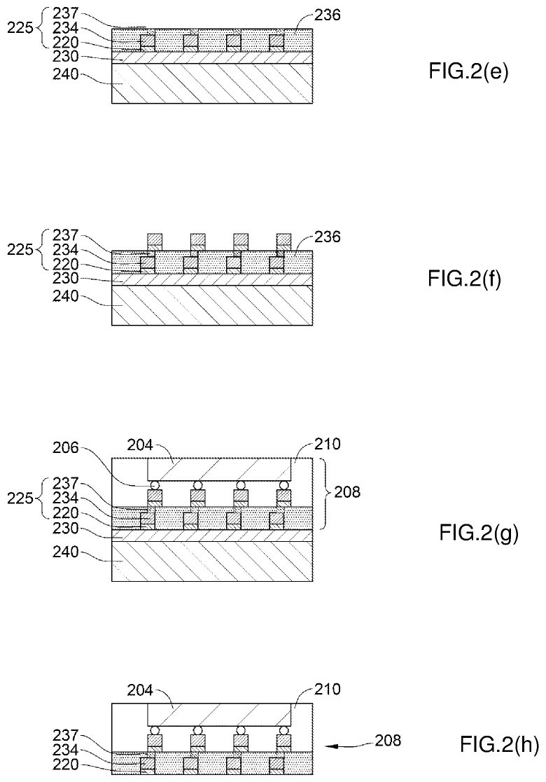

Please refer to FIG. 2, which is a flow chart for schematically illustrating the method of forming a microelectronic structure of the present invention. As shown in FIG. 2(a), the composition for forming the sacrificial layer is applied to the upper surface 242 of the carrier substrate 240 to form the carrier substrate 240 with the laser releasable sacrificial layer 230 on the upper surface 242. The stack 250 (including the carrier substrate 240 and the sacrificial layer 230) may be formed according to any of the methods described above for the temporary bonding method, including process conditions and resulting properties. The sacrificial layer 230 is preferably formed directly on the upper surface 242 of the carrier substrate 240, that is, without any intermediate layer therebetween, as shown in this embodiment. The stack 250 has an upper surface 252 away from the carrier substrate 240.

Next, as shown in FIG. 2(b), a seed layer 220 is deposited on the upper surface 252 according to the conventional method. Then, the seed layer 220 can be subjected to steps such as photoresist coating, patterning and electroplating according to known methods again to form the structure shown in FIG. 2(c), in which the metal 234 and the photoresist 232 are formed on the seed layer 220. Next, the photoresist is removed and the metal is etched to form the structure shown in FIG. 2(d). Afterwards, the dielectric layer 236 is coated, patterned and cured to form the structure shown in FIG. 2(e). In this way, the formation of the first RDL 225 (composed of the seed layer 220, the metal 234 and the metal 237) can be achieved. The steps as shown in FIG. 2(b) to FIG. 2(e) can be repeated multiple times as required to generate multiple RDLs (i.e., 2 RDLs in the specific example shown in FIG. 2(f)). In this embodiment, the metal 234 and the metal 237 are the same metal.

Referring to FIG. 2(g), after the desired number of RDLs have been formed, the solder balls 206 are attached to the uppermost (last formed) RDL in the conventional manner. The die 204 is bonded to the solder balls 206, followed by the application and grinding of a conventional epoxy molding layer 210 to form the FOWLP (fan-out wafer-level package) structure 208. Finally, laser is applied to the carrier substrate 240 to decompose or ablate all or part of the laser releasable sacrificial layer 230. After the application of laser, the carrier substrate 240 will be released and separated from the FOWLP structure 208 to obtain the FOWLP structure 208 (FIG. 2(h)), and any remaining sacrificial layer 230 will be removed with the aqueous alkaline solution.

The above-mentioned process for forming the fan-out wafer-level package structure is only one example of such a process that can be performed using the composition of the present invention as a build-up layer, and can be modified according to user needs. For example, the number of RDL layers and the number and location of solder balls and dies can be varied as desired. Such configurations will be understood and customized by people having ordinary skill in the art to which this invention pertains.

In order to highlight the effect of the present invention, the inventor completes the examples and comparative examples in the manner set forth below. The following examples and comparative examples will further illustrate the present invention, but are not intended to limit the scope of the present invention. All the changes and modifications made by those skilled in the technical field of the present invention without departing from the spirit of the present invention fall within the scope of the present invention.

### Example 1: Polyamic Acid for Forming the Sacrificial Layer

In this example, 7.61 g of 3,5-diaminobenzoic acid was dissolved in 113.16 g of γ-butyrolactone (GBL) in a 250 mL three-neck round bottom flask. Subsequently, 11.11 g of 2,2′-bis-(dicarboxyphenyl)hexafluoropropane dianhydride (6FDA) and 6.2 g of bicyclo[2.2.2]oct-7-ene-2,3,5,6-tetracarboxylic dianhydride was added to the reaction mixture as a solid. The reaction was carried out with stirring at room temperature for 24 hours.

### Example 2: Polyamic Acid for Forming the Sacrificial Layer

In this example, 7.61 g of 3,5-diaminobenzoic acid was dissolved in 113.16 g of γ-butyrolactone (GBL) in a 250 mL three-neck round bottom flask. Subsequently, 11.11 g of 2,2′-bis-(dicarboxyphenyl)hexafluoropropane dianhydride (6FDA) and 7.36 g of 3,3′,4,4′-biphenyl tetracarboxylic dianhydride (BPDA) was added to the reaction mixture as a solid. The reaction was carried out with stirring at room temperature for 24 hours.

### Example 3: Polyamic Acid for Forming the Sacrificial Layer

In this example, 14.31 g of 6,6′-bisamino-3,3′-methylene dibenzoic acid was dissolved in 113.16 g of γ-butyrolactone (GBL) in a 250 mL three-neck round bottom flask. Subsequently, 11.11 g of 2,2′-bis-(dicarboxyphenyl)hexafluoropropane dianhydride (6FDA) and 8.06 g of 3,3′,4,4′-benzophenone tetracarboxylic dianhydride (BTDA) was added to the reaction mixture as a solid. The reaction was carried out with stirring at room temperature for 24 hours.

### Example 4: Polyimide for Forming the Sacrificial Layer

In this example, 14.31 g of 6,6′-bisamino-3,3′-methylene dibenzoic acid was dissolved in 113.16 g of γ-butyrolactone (GBL) in a 250 mL three-neck round bottom flask. Subsequently, 12.41 g of bicyclo[2.2.2]oct-7-ene-2,3,5,6-tetracarboxylic dianhydride was added to the reaction mixture as a solid. After adding 1.67 g of isoquinoline, the temperature was raised to 180° C. for dehydration reaction, and the reaction lasted for 4 hours.

### Example 5: Polyamideimide for Forming the Sacrificial Layer

In the reaction vessel, 10 mmol of 6,6′-bisamino-3,3′-methylene dibenzoic acid was added and dissolved in dimethylacetamide. Stirring under nitrogen atmosphere, the solvent amount was equivalent to the total solid weight component concentration of 15% by weight. After complete dissolution, 2 mmol of 1,2,3,4-cyclobutanetetracarboxylic dianhydride (CBDA) and 3 mmol of 6FDA were added and stirred for 4 hours to dissolve and react, and then the temperature of the solution was maintained at 15° C. while 5 mmol of terephthaloyl chloride (TPC) was added, followed by reaction with stirring for 12 hours. Next, 15 mmol of pyridine and 30 mmol of acetic anhydride were added and stirred for 30 minutes, and then the temperature was raised to 70° C., followed by stirring for 1 hour and then cooling to normal temperature. Finally, a large amount of methanol was used for precipitation, and the precipitated solid was pulverized by a pulverizer, followed by drying into powder through vacuum drying.

### Example 6: Polyamideimide for Forming the Sacrificial Layer

In the reaction vessel, 10 mmol of 6,6′-bisamino-3,3′-methylene dibenzoic acid was added and dissolved in dimethylacetamide. Stirring under nitrogen atmosphere, the solvent amount was equivalent to the total solid weight component concentration of 15% by weight. After complete dissolution, 4 mmol of CBDA and 5 mmol of 6FDA were added and stirred for 4 hours to dissolve and react, and then the temperature of the solution was maintained at 15° C. while 1 mmol of TPC was added, followed by reaction with stirring for 12 hours. Next, 15 mmol of pyridine and 30 mmol of acetic anhydride were added and stirred for 30 minutes, and then the temperature was raised to 70° C., followed by stirring for 1 hour and then cooling to normal temperature. Finally, a large amount of methanol was used for precipitation, and the precipitated solid was pulverized by a pulverizer, followed by drying into powder through vacuum drying.

The alkali-soluble polymers of Examples 1 to 6 were dispersed or dissolved in dimethylacetamide, coated on a glass of 700 μm with a thickness of about 1 μm, and then placed in an oven and backed at 150° C. for 2 minutes to dry the surface, followed by being baked at 300° C. for half an hour to obtain a temporary bonding composition film (A) temporarily placed on the glass surface. After being removed from the glass, a temporary bonding composition film (B) of the present invention with a thickness of about 1 μm could be obtained.

Titanium Copper Plated Test

For the film (A) made in Examples 1 to 6, a Ti/Cu layer (the thickness of Ti/Cu were respectively 100 nm/500 nm) was set on the film (A). With respect to the titanium copper plated test, if there is no crack on the copper film-plated surface after 2 hours of high-temperature aging at a temperature of 230° C., it is passed (V), and if there are cracks, it is failed (X).

Thermal Cracking Temperature

For the film (B) made in Examples 1 to 6, the surrounding temperature was raised to 700° C. from 25° C. with a rate of 10° C./min in air environment, and the temperature at which 5% by weight of the film (B) was lost was measured by thermogravimetric analyzer (TGA), which was the Td5 thermal cracking temperature.

Coefficient of Thermal Expansion (CTE)

The CTE value and glass transition temperature were measured from 50° C. to 200° C. with a thermomechanical analyzer (TA Instrument TMA Q400EM). Before the thermal analysis, all the temporary bonding composition films (B) were thermally treated at 220° C. for 1 hour, and then the glass transition temperature was measured by TMA. The measurement was carried out in the film mode, in which the heating rate was 10° C./min and the load was applied constantly at 30 mN. Similarly, the linear thermal expansion coefficient was measured by TMA at a temperature of 50-200° C., the load strain was 30 mN, and the heating rate was 10° C./min.

Adhesion

For the films (A) made in Examples 1 to 6, the evaluation method of adhesion adopted the cross-cut adhesion test, and the test method used a hundred knife to draw 10×10 (100) 1 mm×1 mm small grids on the surface of the test sample (glass material), with each drawn line as deep as the bottom layer. Afterwards, a brush was used to clean up the fragments in the test area, and then the small grids to be tested were firmly stuck with the adhesive tape, which was then wiped vigorously with an eraser to increase the contact area and strength between the tape and the tested area. Next, one end of the tape was grabbed with hand and the tape was quickly torn off in a vertical direction. The evaluation results are shown in Table 5 below, in which a test result of 5B indicates good adhesion.

Debonding Test

The films (A) made in Examples 1 to 6 were debonded by irradiation with laser light having energy of 230 mJ/cm² and a wavelength of 308 nm. If the film can be peeled off successfully after debonding, it is passed (V), and if it cannot be peeled off, it is failed (X).

Chemical Resistance Test

The films (A) made in Example 1 to Example 6 were soaked in different chemicals listed in Table 1 below for 10 minutes, and then measured with a tension meter. When the measured result was higher than 300 g/cm, it represented good chemical resistance.

TABLE 1

| | Example 1 | Example 2 | Example 3 | Example 4 | Example 5 | Example 6 |
|---|---|---|---|---|---|---|
| Titanium copper | V | V | V | V | V | V |
| plated test | | | | | | |
| Td5 | 440 | 480 | 483 | 420 | 462 | 460 |
| CTE | 45 | 39 | 41 | 55 | 10 | 42 |
| Debonding test | V | V | V | V | V | V |
| Adhesion | 5B | 5B | 5B | 5B | 5B | 5B |
| Chemical | g/cm | g/cm | g/cm | g/cm | g/cm | g/cm |
| resistance | | | | | | |
| NMP | 355 | 320 | 370 | 400 | 380 | 340 |
| 30% HCl | 323 | 348 | 360 | 380 | 400 | 360 |
| 3% NaOH | Dissolved | Dissolved | Dissolved | Dissolved | Dissolved | Dissolved |
| PGMEA | 331 | 329 | 373 | 389 | 373 | 350 |
| TMAH 2.38% | 340 | 330 | 362 | 382 | 388 | 360 |
| Methanol | 335 | 340 | 375 | 392 | 390 | 365 |
| Acetone | 326 | 332 | 368 | 397 | 387 | 355 |

From the above, it can be seen that the sacrificial layer of the present invention not only has good heat resistance, chemical resistance and debonding property, but also has a low coefficient of thermal expansion, and can be easily removed with the alkaline aqueous solution. Therefore, it is very suitable for temporary bonding process and redistribution layer process.

However, the above describes preferred embodiments of the present invention only and cannot be used to limit the scope of the present invention, which means that all the simple and equivalent changes and modifications made according to the claims and the description of the present invention still fall within the scope covered by the present invention.

### REFERENCE NUMERALS

10 first substrate
12 upper surface
14 lower surface
20 adhesive layer
22 upper surface
30 sacrificial layer
40 second substrate
42 upper surface (first surface)
44 lower surface
50 stack precursor
60 another stack precursor
100 stack
204 die
206 solder ball
208 FOWLP (fan-out wafer-level package) structure
210 epoxy molding layer
220 seed layer
225 RDL (redistribution layer)
230 sacrificial layer
232 photoresist
234 metal
236 dielectric layer
237 metal
240 carrier substrate
242 upper surface
250 stack
252 upper surface

What is claimed is:

1. A temporary bonding method, comprising:
providing a stack comprising:
a first substrate having an upper surface and a lower surface;
an adhesive layer in contact with the lower surface;
a second substrate having a first surface; and
a sacrificial layer disposed between the first surface and the adhesive layer; and
applying laser energy to the sacrificial layer to facilitate separation of the first substrate from the second substrate,
wherein the sacrificial layer is formed by a composition comprising an alkali-soluble polymer; and a solvent for dispersing or dissolving the alkali-soluble polymer, wherein the alkali-soluble polymer contains a divalent residue of a diamine having a carboxyl group, and the alkali-soluble polymer comprises polyamic acid, polyimide or polyamideimide.

2. The method of claim 1, further comprising washing the adhesive layer with an alkaline aqueous solution to remove the sacrificial layer remaining on a surface of the adhesive layer after the step of applying laser energy to the sacrificial layer.

3. The method of claim 2, wherein the alkaline aqueous solution is 3 to 5% by weight of an aqueous alkali metal hydroxide solution or an aqueous alkali metal carbonate solution.

4. The method of claim 1, wherein the divalent residue of the diamine having the carboxyl group comprises the following group: 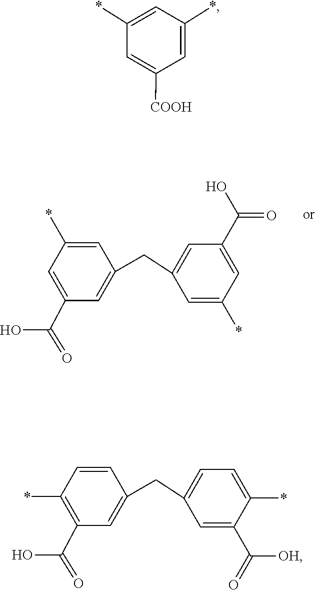
wherein * indicates a connection point.

5. The method of claim 1, wherein the sacrificial layer has a thermal expansion coefficient of less than 50 ppm/° C.

6. A method of forming a microelectronic structure, comprising:
forming a sacrificial layer on a surface of a substrate; and
forming a redistribution layer on the sacrificial layer,
wherein the sacrificial layer is formed by a composition comprising an alkali-soluble polymer; and a solvent for dispersing or dissolving the alkali-soluble polymer, wherein the alkali-soluble polymer contains a divalent residue of a diamine having a carboxyl group, and the alkali-soluble polymer comprises polyamic acid, polyimide or polyamideimide.

7. The method of claim 6, further comprising forming one or more additional redistribution layers on the redistribution layer.

8. The method of claim 6, further comprising applying laser energy to the sacrificial layer to separate the redistribution layer from the substrate after forming the redistribution layer.

9. The method of claim 8, further comprising washing the redistribution layer with an alkaline aqueous solution to remove the sacrificial layer remaining on a surface of the redistribution layer after applying laser energy to the sacrificial layer.

10. The method of claim 9, wherein the alkaline aqueous solution is 3 to 5% by weight of an aqueous alkali metal hydroxide solution or an aqueous alkali metal carbonate solution.

11. The method of claim 6, wherein the divalent residue of the diamine having the carboxyl group comprises the following group: 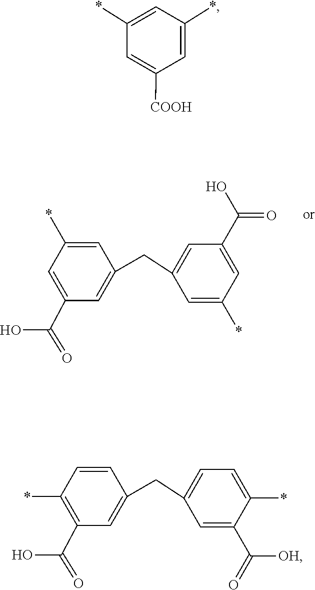
wherein * indicates a connection point.
